(19) United States
(12) Patent Application Publication
(10) Pub. No.: US 2022/0344899 A1
(43) Pub. Date: Oct. 27, 2022

(54) OPTOELECTRONIC SEMICONDUCTOR CHIP COMPRISING A CONTACT ELEMENT AND METHOD OF MANUFACTURING AN OPTOELECTRONIC SEMICONDUCTOR CHIP

(71) Applicant: OSRAM Opto Semiconductors GmbH, Regensburg (DE)

(72) Inventors: Roberto DOSSI, Berlin (DE); Massimo Cataldo MAZZILLO, Hamburg (DE)

(21) Appl. No.: 17/760,965

(22) PCT Filed: Sep. 18, 2019
(86) PCT No.: PCT/EP2019/075023

§ 371 Date: Mar. 16, 2022

(51) Int. Cl. H01S 5/042; H01S 5/02326; H01S 5/42; H01S 5/183; H01S 5/02253; H01S 5/02

(52) U.S. Cl. CPC H01S 5/0421; H01S 5/02326; H01S 5/423; H01S 5/18388; H01S 5/02253; H01S 5/0201; H01S 5/18308

(57) ABSTRACT

An optoelectronic semiconductor chip comprises a semiconductor body including a plurality of active regions configured to generate electromagnetic radiation, the plurality of active regions being arranged in a horizontal plane. The optoelectronic semiconductor chip further comprises a conductive member configured to electrically connect at least two adjacent ones of the active regions with each other, the conductive member being arranged over a first main surface of the semiconductor body. The optoelectronic semiconductor chip further comprises a contact element extending from the first main surface to a second main surface of the semiconductor body and being electrically connected to at least one of the active regions via a contact material over the first main surface, and an optical element arranged over the first main surface of the semiconductor body.

### CROSS-REFERENCE TO RELATED APPLICATIONS

This patent application is a national stage entry from International Application No. PCT/EP2019/075023, filed on Sep. 18, 2019, published as International Publication No. WO 2021/052574 A1 on Mar. 25, 2021, the entire contents of all of which are incorporated by reference herein.

### BACKGROUND OF THE INVENTION

Laser light sources such as semiconductor laser diodes are increasingly employed in mobile communication devices. For example, these laser diodes are implemented as surface emitting lasers, i.e. laser diodes in which the generated laser light is emitted via a main surface of semiconductor body.

It is an object of the present invention to provide an improved optoelectronic semiconductor chip. Further, it is an object of the present invention to provide an improved method of manufacturing an optoelectronic semiconductor chip.

### SUMMARY OF THE INVENTION

According to embodiments, the above object is achieved by the claimed matter according to the independent claims. Further developments are defined in the dependent claims.

According to embodiments, an optoelectronic semiconductor chip comprises a semiconductor body including a plurality of active regions configured to generate electromagnetic radiation, the plurality of active regions being arranged in a horizontal plane. The optoelectronic semiconductor chip further comprises a conductive member configured to electrically connect at least two adjacent ones of the active regions with each other, the conductive member being arranged over a first main surface of the semiconductor body. The optoelectronic semiconductor chip further comprises a contact element extending from the first main surface to a second main surface of the semiconductor body and being electrically connected to at least one of the active regions via a contact material over the first main surface and an optical element arranged over the first main surface of the semiconductor body.

The optical element may comprise a lens attached to a carrier.

For example, the optical element may be arranged over the first main surface of the semiconductor body so that a gap is formed between the optical element and the first main surface of the semiconductor body. The carrier may form part of a housing of the optoelectronic semiconductor chip.

According to embodiments, the lens is arranged on a side of the optical element facing the semiconductor body. Alternatively, the lens may be arranged on a side of the optical element remote from the semiconductor body.

The optoelectronic semiconductor chip may further comprise a spacer material, the spacer material being arranged over portions of the first main surface of the semiconductor body, further portions of the first main surface of the semiconductor body being uncovered with the spacer material. The optical element may be attached to the first main surface of the semiconductor body via the spacer material.

According to embodiments, the optoelectronic semiconductor chip may comprise a plurality of laser diodes, at least some of the active regions forming part of the laser diodes. For example, the laser diodes may be vertical-cavity surface-emitting lasers.

The semiconductor body may comprise a semiconductor substrate and epitaxially grown semiconductor layers over the semiconductor substrate, the epitaxially grown semiconductor layers comprising a first semiconductor layer of a first conductivity type and a second semiconductor layer of a second conductivity type. The active region may form part of the epitaxially grown semiconductor layers or may be arranged in the epitaxially grown semiconductor layers. According to an alternative interpretation, some of the epitaxially grown semiconductor layers may form the active region. The active region may be arranged between the first semiconductor layer and the second semiconductor layer.

The optoelectronic semiconductor chip may further comprise a first contact portion electrically connected to the first semiconductor layer and a second contact portion electrically connected to the second semiconductor layer, the first and the second contact portions being arranged adjacent or in close spatial relationship to a second main surface of the semiconductor substrate.

For example, the second main surface of the semiconductor substrate may form part of a housing of the optoelectronic semiconductor chip.

An electronic device comprises the optoelectronic semiconductor chip as defined above. For example, the electronic device may selected from the group comprising a time-of-flight sensor, a mobile phone, a smartphone, a tablet, a computer, a laptop, a vacuum cleaner or another home appliance, sanitary or other facilities.

According to embodiments, a method of manufacturing an optoelectronic semiconductor chip comprises forming a wafer comprising a semiconductor body including forming a plurality of active regions in a horizontal plane, the active regions being configured to generate electromagnetic radiation. The method further comprises forming a conductive member over a first main surface of the semiconductor body, the conductive member being configured to electrically connect at least two adjacent ones of the active regions with each other. The method further comprises forming an optical element over the first main surface of the semiconductor body and forming a contact element extending from the first main surface to a second main surface of the semiconductor body. The method further comprises electrically connecting the contact element with a contact material over the first main surface.

The method may further comprise dicing the wafer into single chips after electrically connecting the contact element with a contact material over the first main surface.

According to embodiments, forming the optical element comprises attaching a carrier to the semiconductor body. For example, the carrier may be attached before forming the contact element.

According to embodiments, the carrier may comprise a lens. According to further embodiments, the carrier without a lens may be attached to the semiconductor body. For example, the lens may be attached to the carrier after performing further processing steps. For example, the lens may be attached to the carrier after forming the contact element and before dicing the wafer into single chips.

According to embodiments, attaching the carrier to the semiconductor body may comprise forming a spacer material over portions of the first main surface and leaving further portions of the first main surface uncovered and attaching the carrier to the spacer material.

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

### BRIEF DESCRIPTION OF THE DRAWINGS

FIG. 1A shows a vertical cross-sectional view of a semiconductor chip according to embodiments.

FIG. 1B shows a vertical cross-sectional view of a semiconductor chip according to further embodiments.

FIGS. 2A to 2H illustrates vertical cross-sectional views of a workpiece when manufacturing a semiconductor chip according to embodiments.

FIGS. 3A to 3C illustrates vertical cross-sectional views of a workpiece when manufacturing a semiconductor chip according to further embodiments.

FIG. 4 summarizes a method according to embodiments.

FIG. 5 is a schematic view of an electronic device according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to embodiments, the second semiconductor substrate may be a GaAs substrate, a GaN substrate, a GaP substrate or a silicon substrate.

Depending on the purpose of use, the semiconductor may be based on a direct or an indirect semiconductor material. Examples of semiconductor materials particularly suitable for generation of electromagnetic radiation comprise nitride-compound semiconductors, by which e.g. ultraviolet or blue light or longer wavelength light may be generated, such as GaN, InGaN, AlN, AlGaN, AlGaInN, AlGaInBN, phosphide-compound semiconductors, by which e.g. green or longer wavelength light may be generated such as GaAsP, AlGaInP, GaP, AlGaP, as well as further semiconductor materials including GaAs, AlGaAs, InGaAs, SiC, ZnSe, ZnO, Ga₂O₃, diamond, hexagonal BN and combinations of these materials. Further examples of semiconductor materials may as well be silicon, silicon-germanium and germanium. The stoichiometric ratio of the compound semiconductor materials may vary. In the context of the present specification, the term “semiconductor” further encompasses organic semiconductor materials.

The terms “lateral” and “horizontal” as used in this specification intends to describe an orientation parallel to a first surface of a substrate or semiconductor body. This can be for instance the surface of a wafer or a die.

The term “vertical” as used in this specification intends to describe an orientation which is arranged perpendicular to the first surface of a substrate or semiconductor body.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The term “electrically connected” further comprises tunneling contacts between connected elements.

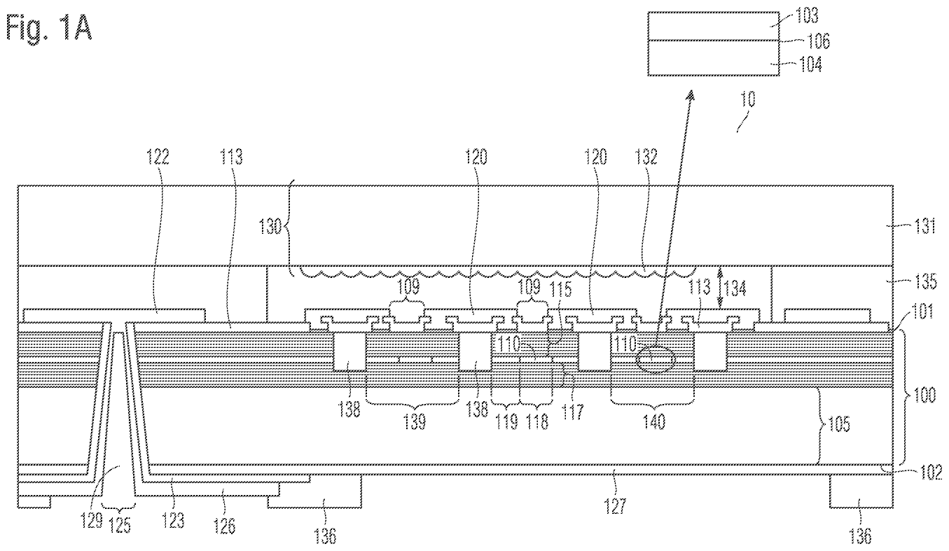

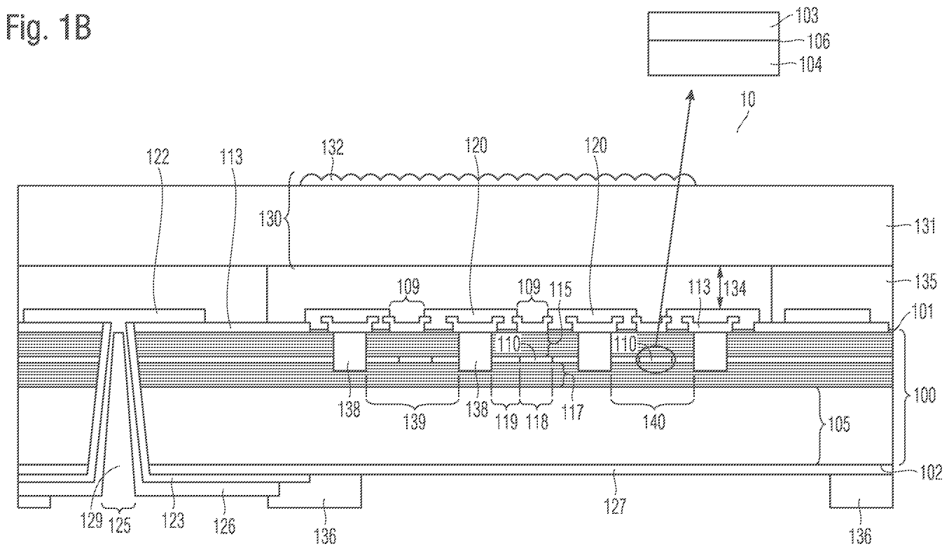

FIG. 1A shows a vertical cross-sectional view of an optoelectronic semiconductor chip 10 according to embodiments. The optoelectronic semiconductor chip 10 comprises a semiconductor body 100. The semiconductor body 100 comprises a plurality of active regions 110 configured to generate electromagnetic radiation. The plurality of active regions 110 are arranged in a horizontal plane. The optoelectronic semiconductor chip further comprises a conductive member 120 that is configured to electrically connect at least two adjacent ones of the active regions 110 with each other. The conductive member 120 is arranged over a first main surface 101 of the semiconductor body 100.

The optoelectronic semiconductor chip 10 further comprises a contact element 125 that extends from the first main surface 101 to a second main surface 102 the semiconductor body 100. The contact element 125 is electrically connected to at least one of the active regions 110 via a contact material 122 over the first main surface 101. The optoelectronic semiconductor chip 10 further comprises an optical element 130 that is arranged over the first main surface 101 of the semiconductor body 100.

The optoelectronic semiconductor chip comprises laser diodes 140. At least some of the active regions 110 form part of the laser diodes 140. For example, the laser diodes 140 are connected in parallel.

The laser diodes 140 may be implemented as vertical-cavity surface-emitting lasers which are configured to emit light in a vertical direction, i.e. in a direction perpendicular to a stacking direction of the semiconductor layers. The active region 110 may comprise an active layer 106 that is configured to generate electromagnetic radiation. The active layer 106 of the active region 110 may, for example, comprise a pn junction, a double heterostructure, a single quantum well (SQW) or a multi quantum well (MQW) for generating radiation. The wording “quantum well” does not further specify the dimension of the quantization. Accordingly, the term “quantum well” comprises quantum wells, quantum wires and quantum dots as well as any combination of these layers. For example, the active region 110 may be based on a nitride, a phosphide or arsenide compound semiconductor material. The plurality of active regions 110 may be formed in the same epitaxial layers, respectively, and may be separated e.g. by isolation trenches 138.

The semiconductor body 100 may comprise, e.g. a semiconductor substrate 105, such as a growth substrate. For example, the substrate material may comprise GaAs. According to further embodiments, the substrate 105 may as well comprise GaN, GaP or other semiconductor materials. According to embodiments, a first semiconductor layer 103 of a first conductivity type, e.g. p type, and a second semiconductor layer 104 of a second conductivity type, e.g. n type, may be arranged adjacent to the active layer 106. A thickness of the active region 110 may be at least equal to the effective emitted wavelength (λ/n, wherein n denotes the refractive index of the active region) so that a cavity may be formed. A first cavity mirror 115 and a second cavity mirror 117 may be arranged adjacent to the active region 110 and on opposing sides of the active region 110. Accordingly, standing waves may be generated within the cavity. For example, a thickness of the active layer 106 may be several 10 nm and the thickness of the cladding layers may be approximately 10 to 20 nm. The second cavity mirror 117 may be arranged between the active region 110 and the substrate 105. The first cavity mirror 115 and the second cavity mirror 117 form an optical cavity for the electromagnetic radiation generated within the active region 110. For example, the first cavity mirror 115 may be an outcoupling mirror of the laser radiation. For example, the first cavity mirror 115 may have a lower reflectivity than the second cavity mirror 117. For example, the second cavity mirror 117 may have a total reflectivity of 99.8% or more for the generated laser radiation. The laser radiation is generated by means of induced emission.

According to embodiments, the first and the second cavity mirrors 115, 117 may comprise first layers of a first composition and second layers of a second composition which are alternately stacked. For example, the first layers may have a high refractive index (n>1.7) and the second layers may have a low refractive index (n<1.7). The layer stack comprising first and second layers may form a Bragg reflector. For example, the layer thickness may be λ/4 or a multiple of λ/4, wherein λ denotes the wavelength of the light to be reflected. The first or the second cavity mirror 115, 117 may comprise two to fifty different layers. A typical layer thickness of the single layers may be 30 to 90 nm, e.g. approximately 50 nm. The layer stack may further comprise one or more layers having a thickness larger than approximately 180 nm, e.g. larger than 200 nm. For example, the layers of the first cavity mirror 115 may be of a first conductivity type, e.g. p-type. Further, the layers of the second cavity mirror 117 may be of a second conductivity type, e.g. n-type. The layers of the first and second cavity mirrors 115, 117 may be epitaxially grown. According to further embodiments, the first and/or the second cavity mirror 115, 117 may be composed of dielectric layers.

The semiconductor body 100 comprising the cavity mirrors 115, 117 and the active region may be patterned into mesas 139, e.g. by forming isolation trenches 138. For example, the isolation trenches 138 may extend from the first main surface 101 to the second cavity mirror 117. The isolation trenches 138 may be filled within insulating material such as a polymer. Further, an aperture 118 is formed in the active region, e.g. by increasing an electric resistivity in the portions adjacent to the aperture in the active region 118. According to embodiments, the electric resistivity may be increased by suitably amorphizing these portions. By implementing this portion of the semiconductor body as a blocking layer 119, electrical current is prevented from flowing across this region 119. For example, a diameter of the aperture 118 may be less than 25 μm, e.g. 10 to 15 μm.

For example, adjacent active regions 110 may be electrically connected by conductive members 120. E.g. the conductive members 120 may be arranged over a first main surface 101 of the semiconductor body, being electrically insulated by means of a dielectric layer 113. For example, a material of the conductive member 120 may be gold.

For example, a thickness of the dielectric layer may be approximately 100 to 300 nm, e.g. approximately 200 nm. The thickness of the conductive member 120 may be for example several μm, e.g. 1 to 3 μm. The thickness of the first cavity mirror may be approximately 2 to μm, e.g. 3 μm. A thickness of the active region may be approximately 200 nm. A depth of the isolation trench may be approximately more than 3 μm, e.g. μm. In particular, a depth of the trench may be larger than a thickness of the first cavity mirror 115. A thickness of the second cavity mirror 117 may be larger than a thickness of first cavity mirror. For example, a thickness of the second cavity mirror may be approximately more than μm, e.g. 5 μm.

As is to be appreciated, the above layer thicknesses and dimensions are indicated for illustrative purposes and may vary depending on the size of the optoelectronic semiconductor chip.

Further, an optical element 130 may be arranged over the first main surface 101 of the semiconductor body 100. For example, the optical element 130 may comprise a lens 132 that is attached to a carrier 131. In particular, the optical element 130 may comprise a plurality of lenses. The term “lens” as used within the present specification is intended to mean an assembly of a plurality of lenses unless otherwise specified.

The carrier 131 may be made of a transparent material. For example, the carrier may be a glass carrier or may be made of another transparent material. The lens 132 may be implemented as a micro lens or an assembly of micros lenses. The lens 132 may be made of a polymer material, e.g. an acrylic material. As is illustrated in FIG. 1A, the lens 132 is arranged on a side facing the semiconductor body 100.

The carrier 131 may be attached to the first main surface 101 of the semiconductor body 100 by means of a spacer material 135. The spacer material 135 may for example comprise a polyimide material or another suitable material. The spacer material 135 may be formed over portions of the first main surface 101 while leaving further portions of the first main surface 101 uncovered. When attaching the optical element 130 to the semiconductor body 100 via the spacer material 135, a gap 134 is formed between the light emission area 109 and the optical element 130. As a consequence, the light emission area 109 may be protected by the optical element 130. The thickness of the spacer material 135 may be selected so as to achieve a desired distance between the first main surface of the semiconductor body 100 and the optical element 130.

For example, a thickness of the spacer material 135 may be in a range of more than 5 μm and less than 100 μm. For example, a thickness may be about 40 to 60 μm, e.g. 50 μm.

The semiconductor chip 10 further comprises a contact element 125 that extends from a first main surface 101 of the semiconductor body to a second main surface 102 of the semiconductor body. For example, the contact element 125 may comprise a contact opening 129 that may be formed in the second main surface 102 of the semiconductor body 100. The contact opening 129 may extend from the second main surface 102 to the first main surface 101. An insulating material 123, such as silicon oxide or silicon nitride may be formed over sidewalls of the contact opening 129. Further, a conductive material 126 may formed over the insulating material 123. The conductive material 126 may be in direct contact with a contact material 122. The contact material 122 may be electrically connected to the active region 110 in a plane before or behind the depicted plane of the drawing.

As is further shown in FIG. 1A, a first contact portion 126 may be formed over the second main surface 102. The first contact portion 126 is electrically connected to a semiconductor layer of a first conductivity type of the active region via the contact material 122. A second contact portion 127 may be formed adjacent to the second main surface 102 of the semiconductor body 100. The second contact portion 127 is electrically connected to a semiconductor layer of a second conductivity type of the active region 110. The second contact portion may e.g. formed in contact with the substrate 105. The semiconductor chip 10 further comprises an isolation solder mask 136 that is formed over a second main surface 102 of the semiconductor body 100.

FIG. 1B shows a cross-sectional view of an optoelectronic semiconductor chip 10 according to further embodiments. The optoelectronic semiconductor chip 10 shown in FIG. 1B comprises basically the same elements as the semiconductor chip 10 illustrated in FIG. 1A. Differing from embodiments shown in FIG. 1A, according to FIG. 1B, the lens or lens assembly 132 is arranged on a side of the carrier 131 remote from the semiconductor body 100.

The semiconductor chip 10 shown in FIGS. 1A and 1B forms an optoelectronic semiconductor device in a chip size package. For example, the semiconductor body 100 may comprise a semiconductor substrate 105 and epitaxially grown semiconductor layers. The second main surface of the semiconductor body 100 may be identical with the second main surface of the semiconductor substrate 105. The second main surface of the semiconductor substrate 105 may form part of a housing of the optoelectronic semiconductor chip 10. Moreover, the optical element 130, for example, the carrier 131 may form part of the housing of the optoelectronic semiconductor chip 10. Due to the feature that the optical element 130 is attached to the first main surface 101 of the semiconductor body 100 and, further, terminals of the optoelectronic semiconductor device are electrically connected to a first contact portion 126 and a second contact portion 127 that are arranged over a second main surface 102 of the semiconductor body 100, the size of the package scarcely exceeds the size of the semiconductor chip itself. As a consequence, the optoelectronic semiconductor chip may be formed in a chip size package. At the same time, the light emitting surface of the optoelectronic semiconductor chip may be protected, due to the presence of the optical element 130 that is arranged over the first main surface 101 of the semiconductor body 100.

In particular, when the optical element 130 is attached via a spacer material 135, a gap 134 may be formed between the light emission surface 101 and the optical element. As a consequence, the light emission surface 101 may be further protected. Due to the combination of features that the conductive members 120 are arranged over the first main surface 101 of the semiconductor body 100 and the optical element 130 is arranged over the first main surface 101, a gap 134 being arranged between the light emitting surface and the optical element, it is possible to electrically contact the active region 110 by means of a contact element 125 that extends from the second main surface 102 to the first main surface 110. Due to the presence of this contact element 125, the optoelectronic semiconductor chip may be contacted from a bottom side of the semiconductor chip.

In the following, a method of manufacturing the optoelectronic semiconductor chip will be explained. Starting point is a workpiece 15 that may be e.g. a semiconductor wafer (semiconductor substrate 105) comprising epitaxially grown semiconductor layers and further elements of the optoelectronic semiconductor chip that are formed over the first main surface 101 of the semiconductor body 100 and that are formed over the second main surface 102 of the semiconductor body 100. For example, the semiconductor substrate 105 may be a GaAs substrate. A thickness of the GaAs substrate may be less than 500 μm, e.g. less than 200 μm.

The epitaxially grown layers comprise AlGaAs layers implementing layers of the first and second cavity mirrors 115, 117 and an active region comprising GaAs multi quantum wells. A dielectric layer 113 may be formed over the first main surface 101 of the semiconductor body 100 and may be patterned. Further a conductive layer, e.g. a gold layer may be formed over the dielectric layer and may be patterned to form e.g. the conductive members 109 and further a contact material 122. Further, the semiconductor substrate 105 may be thinned after forming the conductive layer over the first main surface 101 of the semiconductor body. Thereafter, a metal layer may be formed over the second main surface 102 of the semiconductor body 100. The metal layer may form the second contact portion 127 after completing the manufacture process. The semiconductor substrate 105 may be thinned so that a contact opening 129 may be formed in a later processing step.

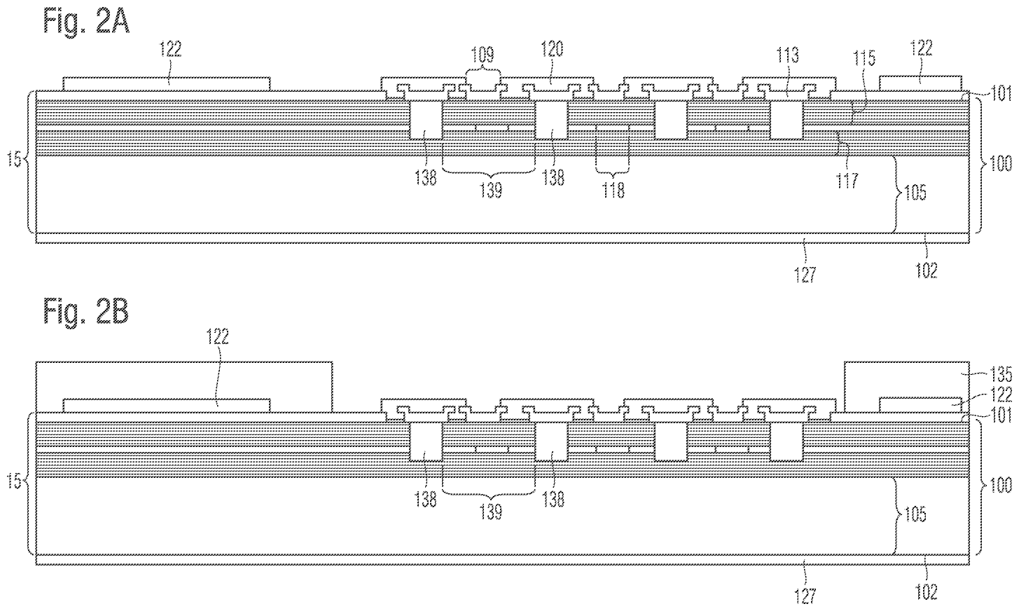

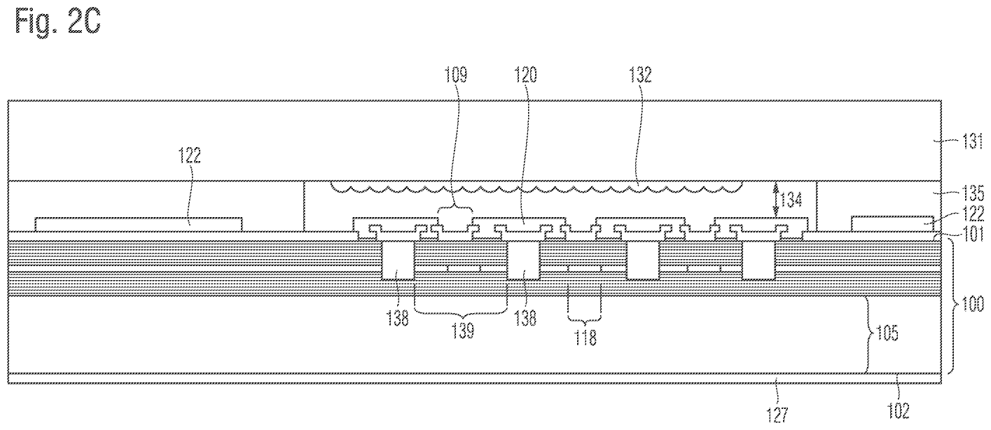

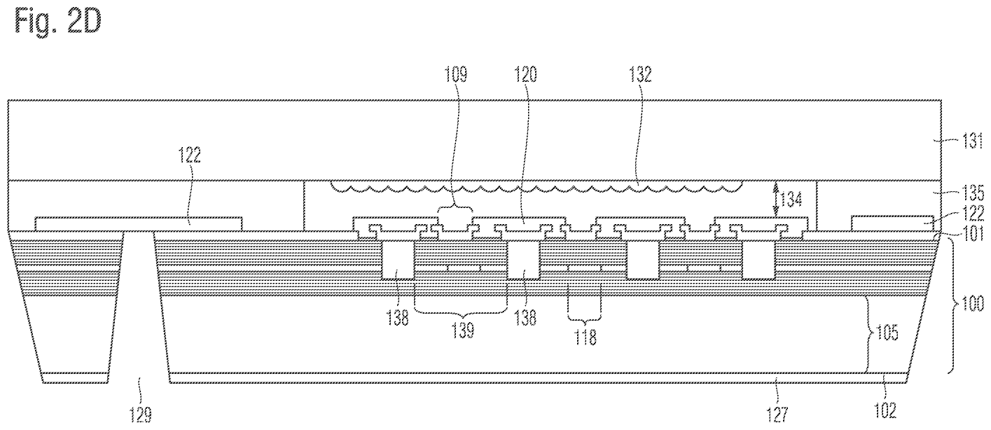

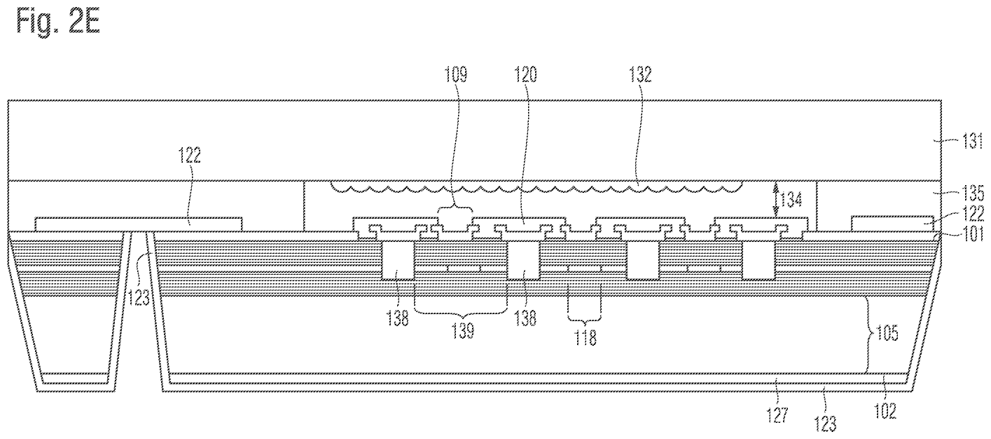

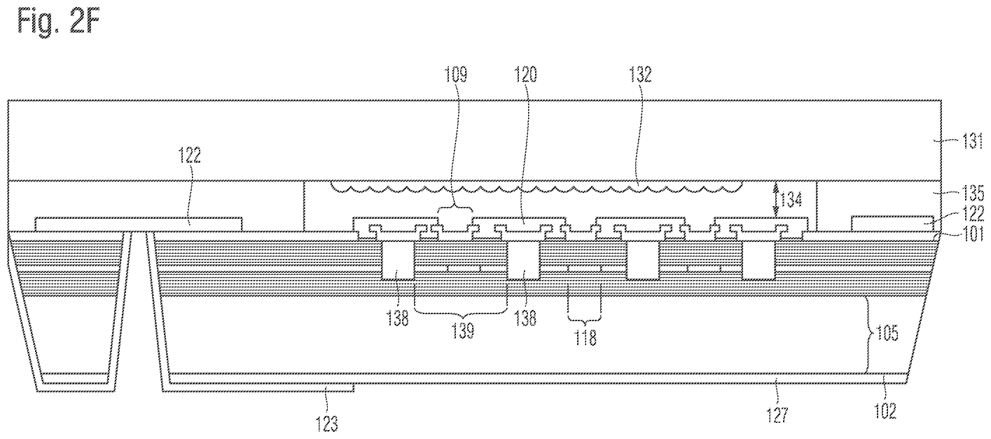

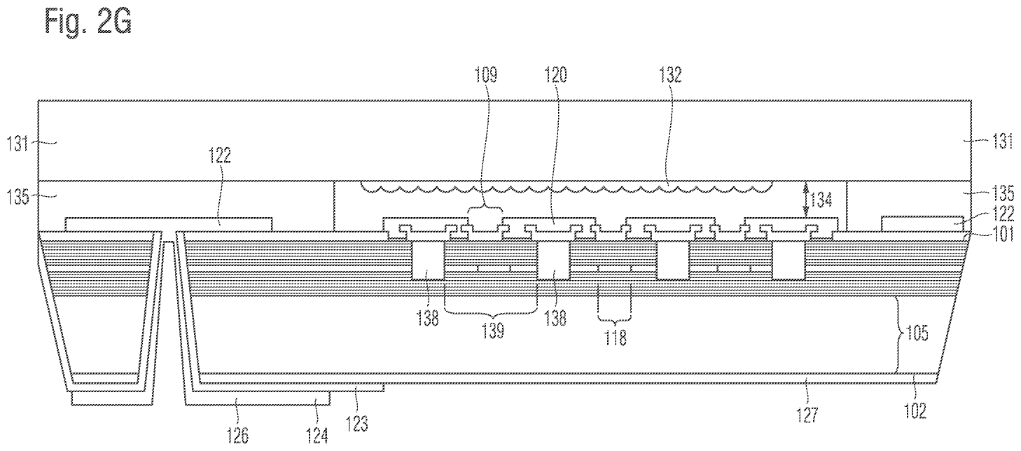

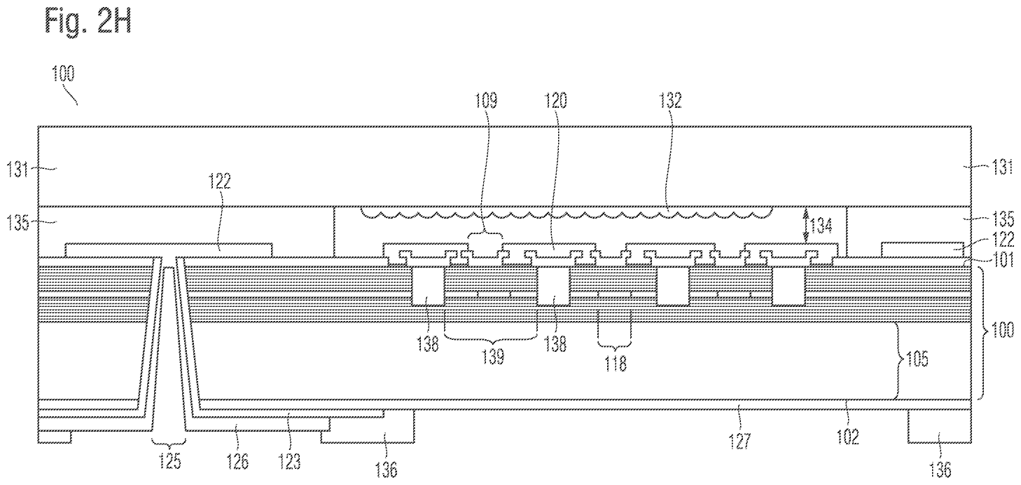

FIG. 2A shows an example of a workpiece.

Thereafter, as is shown in FIG. 2B, portions of a spacer material 135 may be formed over the first main surface 101 of the semiconductor body 100. For example, the portions of the spacer material 135 may be formed in regions in which in a later processing stage, the single chips are to be diced. For example, the spacer material 135 may be formed in a kerf region of the chips. For example, as is shown in FIG. 2B, the spacer material 135 is formed over the contact material 122. For example, the spacer material 135 may be applied by spin coating followed by a process of patterning the spacer material 135, e.g. a photolithographic process followed by etching. According to further implementations, a lift-off process may be used.

Thereafter, the workpiece 15 may be attached to a carrier 131 comprising a lens 132. For example, the lens 132 may be made of a polymer material and may be arranged on a side of the carrier 131 that is adjacent to the workpiece 15. For example, a lateral extension of the lenses or horizontal width may be 10 μm to 50 μm. According to embodiments, more than one lens may be arranged over one mesa. For example, approximately, five lenses may be formed over one mesa 139. A mesa may have a width of approximately more than 10 μm, e.g. 32 μm. Due to the fact that the carrier 131 comprising the lenses 132 is aligned with respect to the workpiece 15, e.g. a wafer, an optical alignment between the light emission area 109 and the lenses may be achieved in a simplified manner. For example, alignment may be achieved using photolithographic alignment methods, e.g. using alignment marks on the carrier 131 and the workpiece 15. The carrier 131 implements a handling carrier for performing the next processing steps. In more detail, the mechanical stability of the workpiece is increased due to the presence of the carrier 131. As has been described, the thickness of the spacer material 135 may be selected so as to achieve desired distance between the first main surface of the semiconductor body 100 and the optical element 130. Accordingly, by setting a thickness of the spacer material 135 in a range of more than 30 μm and less than 100 μm, as discussed above, the distance between the first main surface of the semiconductor body 100 and the optical element 130 may accurately set.

FIG. 2C shows an example of a resulting structure. Thereafter, as is shown in FIG. 2D, contact openings 129 are formed in the semiconductor body 100 from a side of the second main surface 102. The contact opening 129 extends via the semiconductor body 100 to the contact material 122. For example, a diameter of the contact opening 129 may be 10 to 50 μm. For example, the contact opening 129 may be formed by etching, e.g. dry etching. Thereafter, an insulating material 123 is formed over the resulting surface. The insulating material 123 covers the sidewalls of the contact opening 129.

FIG. 2E shows an example of a resulting structure. Thereafter, an etching process is performed so as to pattern the insulating layer 123. In particular, the insulating layer 123 is removed from portions of the second contact portion 127. Further, the insulating layer 123 is removed from a lower surface of the contact material 122.

FIG. 2F shows an example of a resulting structure. Thereafter, a further conductive material 124 may be formed over the resulting backside portion of the workpiece. For example, gold may be deposited and may be further patterned so as to electrically contact the contact material 122. As a result, the first contact portion 126 is formed in close spatial relationship to the second main surface 102 of the semiconductor body 100.

FIG. 2G shows an example of a resulting structure. In the next step, an isolation solder mask 136 may be deposited in order to electrically isolate the first contact portion 126 from the second contact portion 127. Thereafter, the workpiece 15 may be diced into single semiconductor chips.

Generally, the optoelectronic semiconductor chip 10 as described with reference to embodiments herein is intended to mean the semiconductor based piece which results from this dicing process. In more detail, the components of the optoelectronic semiconductor chip have been manufactured on a wafer level.

FIG. 2H shows an example of a resulting optoelectronic semiconductor chip. The optoelectronic semiconductor chip may have a lateral extension of approximately 50 to 500 μm. For example, more than 4, approximately 10×10 light emission areas 109 may be arranged in a single chip.

According to further embodiments, the lens 132 may be arranged on a side of the carrier 131 remote from the semiconductor body 100. For manufacturing the optoelectronic semiconductor chip 10 according to these embodiments, starting from the workpiece illustrated in FIG. 2B, a carrier 131 may be attached to the workpiece 15 in a similar manner as has been discussed before with respect to FIGS. 2B and 2C. Differing from these embodiments, the carrier 131 may not comprise a lens 132.

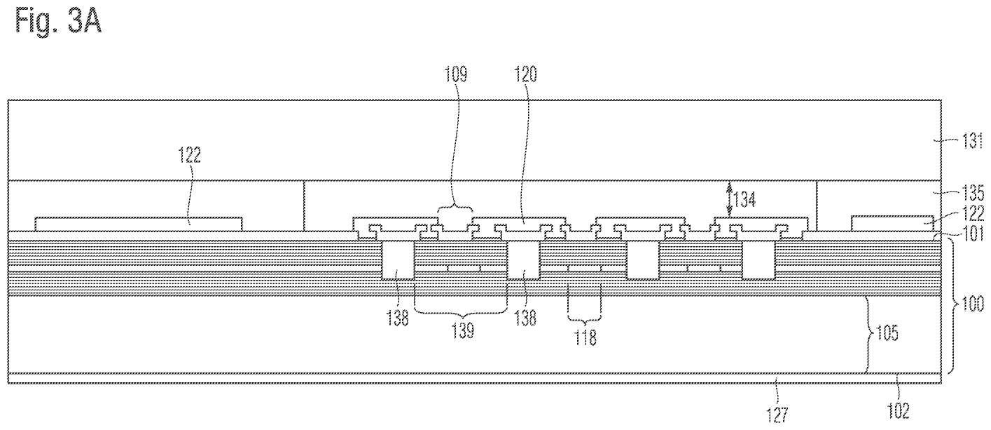

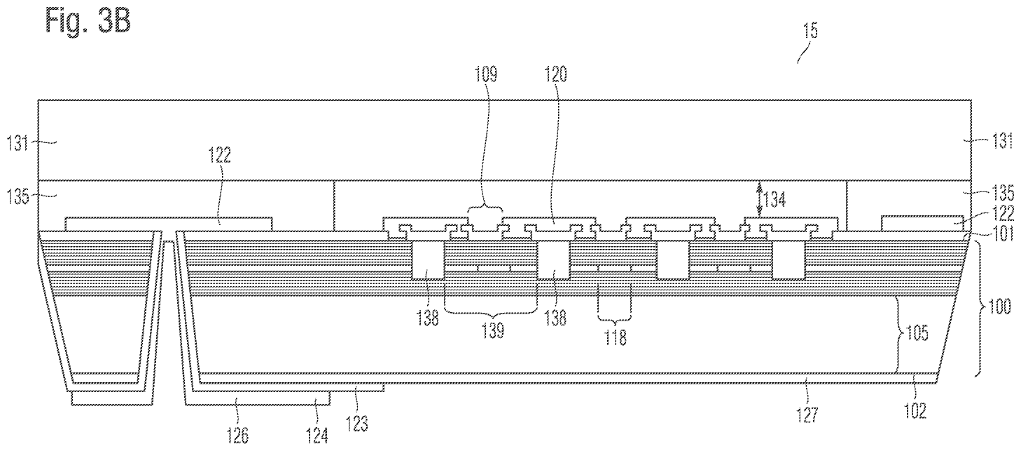

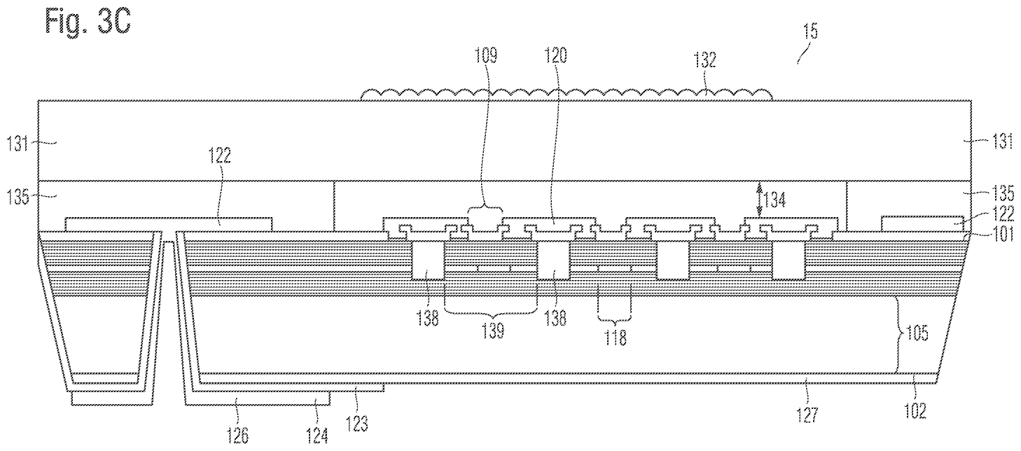

FIG. 3A shows an example of a resulting structure.

Thereafter, the further processing steps which have been described with reference to FIGS. 2D to 2G are performed. FIG. 3B shows an example of a resulting structure.

Then, a lens 132 is attached to a surface of the carrier 131, the surface being remote from the semiconductor body 100. FIG. 3C shows an example of a resulting structure.

Thereafter, the workpiece 15 is diced into single optoelectronic semiconductor chips 10 as e.g. illustrated in FIG. 1B.

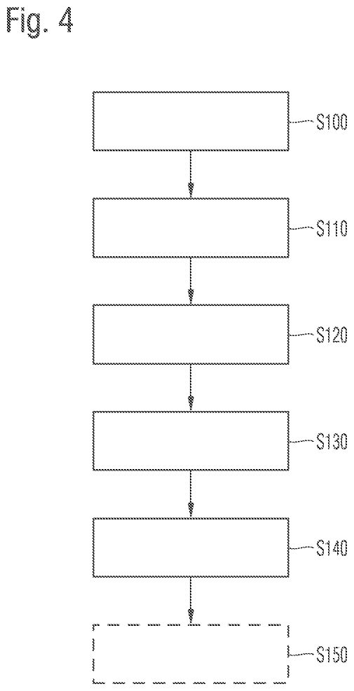

FIG. 4 summarizes the method according to embodiments. As is shown, a method of manufacturing an optoelectronic semiconductor chip comprises forming a wafer comprising a semiconductor body including forming a plurality of active regions in a horizontal plane, the active regions being configured to generate electromagnetic radiation. The method further comprises forming a conductive member over a first main surface of the semiconductor body (S110), the conductive member being configured to electrically connect at least two adjacent ones of the active regions with each other. The method further comprises forming an optical element over the first main surface of the semiconductor body (S120) and forming a contact element extending from the first main surface to a second main surface of the semiconductor body (S130). The method further comprises electrically connecting the contact element with a contact material over the first main surface (S140). The method may further comprise dicing (S150) the wafer into single chips after electrically connecting the contact element with a contact material over the first main surface.

As has been explained above, due to the method described above, the single pixel arrays may be attached to an optical element on a wafer-scale process. Further, electric contacts to the pixel array may be formed in a wafer-scale process. Hence, the optoelectronic semiconductor chip may be manufactured in a simplified and cost-effective manner. Due to the processing on wafer level, it is also possible to perform functional tests on a wafer level whereby the processing may be further simplified. Further, due to the fact that the workpiece is processed using a carrier including the optical element, alignment of the optical element and the light emitting areas 109 may be accomplished in a simple manner. The resulting optoelectronic semiconductor chip implements a chip size package including the optical element and contact portions for contacting the pixel array. As a consequence, the size of the optoelectronic semiconductor device may be reduced.

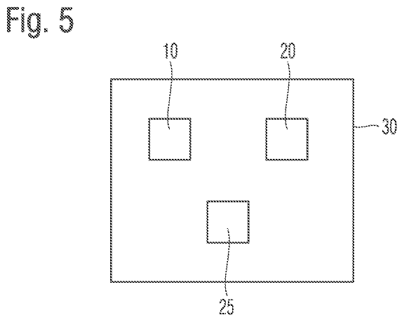

FIG. 5 shows an electronic device 30 comprising the optoelectronic semiconductor chip 10. According to embodiments, the electronic device 30 may be a time-of-flight sensor comprising the optoelectronic semiconductor chip 10 and a detector 20. The detector 20 may be configured to detect electromagnetic radiation that has been emitted by the optoelectronic semiconductor chip and has been reflected by an item such as a user. The electronic device 20 may further comprise a processing device 25. According to embodiments, if the electronic device 20 implements a time-of-flight sensor, the processing device 25 may be configured to process the signals detected by the detector 20. According to embodiments, the processing device 25 may be configured to perform face recognition. According to further embodiments, the electronic device 30 may be a mobile phone, a smartphone, a tablet, a computer, a laptop, a vacuum cleaner or another home appliance, sanitary and other facilities.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1. An optoelectronic semiconductor chip comprising
a semiconductor body including a plurality of active regions configured to generate electromagnetic radiation, the plurality of active regions being arranged in a horizontal plane;
a conductive member configured to electrically connect at least two adjacent ones of the active regions with each other, the conductive member being arranged over a first main surface of the semiconductor body;
a contact element extending from the first main surface to a second main surface of the semiconductor body and being electrically connected to at least one of the active regions via a contact material over the first main surface; and
an optical element arranged over the first main surface of the semiconductor body, the optical element being arranged over the first main surface of the semiconductor body so that a gap is formed between the optical element and the conductive member.

2. The optoelectronic semiconductor chip according to claim 1, wherein the optical element comprises a lens attached to a carrier.

3. (canceled)

4. The optoelectronic semiconductor chip according to claim 2, wherein the lens is arranged on a side of the optical element facing the semiconductor body.

5. The optoelectronic semiconductor chip according to claim 2, wherein the lens is arranged on a side of the optical element remote from the semiconductor body.

6. The optoelectronic semiconductor chip according to claim 2, wherein the carrier forms part of a housing of the optoelectronic semiconductor chip.

7. The optoelectronic semiconductor chip according to claim 1, further comprising a spacer material,
the spacer material being arranged over portions of the first main surface of the semiconductor body, further portions of the first main surface of the semiconductor body being uncovered with the spacer material,
the optical element being attached to the first main surface of the semiconductor body via the spacer material.

8. The optoelectronic semiconductor chip according to claim 1,
comprising a plurality of laser diodes, at least some of the active regions forming part of the laser diodes.

9. The optoelectronic semiconductor chip according to claim 8, wherein the laser diodes are vertical-cavity surface-emitting lasers.

10. The optoelectronic semiconductor chip according to claim 1, wherein the semiconductor body comprises a semiconductor substrate and epitaxially grown semiconductor layers over the semiconductor substrate, the epitaxially grown semiconductor layers comprising a first semiconductor layer of a first conductivity type and a second semiconductor layer of a second conductivity type, the active region forming part of the epitaxially grown semiconductor layers and being arranged between the first semiconductor layer and the second semiconductor layer.

11. The optoelectronic semiconductor chip according to claim 10, further comprising a first contact portion electrically connected to the first semiconductor layer and a second contact portion electrically connected to the second semiconductor layer, the first and the second contact portions being arranged adjacent to a second main surface of the semiconductor substrate.

12. The optoelectronic semiconductor chip according to claim 10, wherein the second main surface of the semiconductor substrate forms part of a housing of the optoelectronic semiconductor chip.

13. An electronic device comprising an optoelectronic semiconductor chip comprising:
a semiconductor body including a plurality of active regions configured to generate electromagnetic radiation, the plurality of active regions being arranged in a horizontal plane;
a conductive member configured to electrically connect at least two adjacent ones of the active regions with each other, the conductive member being arranged over a first main surface of the semiconductor body;
a contact element extending from the first main surface to a second main surface of the semiconductor body and being electrically connected to at least one of the active regions via a contact material over the first main surface; and
an optical element arranged over the first main surface of the semiconductor body, the optical element being arranged over the first main surface of the semiconductor body so that a gap is formed between the optical element and the conductive member.

14. The electronic device according to claim 13, wherein the electronic device is selected from the group comprising a time-of-flight sensor, a mobile phone, a smartphone, a tablet, a computer, a laptop, a vacuum cleaner or another home appliance, sanitary or other facilities.

15. A method of manufacturing an optoelectronic semiconductor chip, comprising:
forming a wafer comprising a semiconductor body including forming a plurality of active regions in a horizontal plane, the active regions being configured to generate electromagnetic radiation;
forming a conductive member over a first main surface 4 of the semiconductor body, the conductive member being configured to electrically connect at least two adjacent ones of the active regions with each other;
forming an optical element over the first main surface of the semiconductor body the optical element being formed over the first main surface of the semiconductor body so that a gap is formed between the optical element and the conductive member;
forming a contact element extending from the first main surface to a second main surface of the semiconductor body, and
electrically connecting the contact element with a contact material over the first main surface.

16. The method according claim 15, further comprising dicing the wafer into single chips after electrically connecting the contact element with a contact material over the first main surface.

17. The method according to claim 15, wherein forming the optical element over the first main surface of the semiconductor body comprises attaching a carrier to the semiconductor body.

18. The method according to claim 17, wherein attaching is performed before forming the contact element.

19. The method according to claim 18, wherein the carrier comprises a lens.

20. The method according to claim 19, further comprising attaching a lens to the carrier after forming the contact element and before dicing the wafer into single chips.

21. The method according to claim 17, wherein attaching the carrier to the semiconductor body comprises:
forming a spacer material over portions of the first main surface and leaving further portions of the first main surface uncovered; and
attaching the carrier to the spacer material.

22. The optoelectronic semiconductor chip according to claim 7, wherein a thickness of the spacer material is larger than 5 μm.
